(19) United States
(12) Patent Application Publication
(10) Pub. No.: US 2011/0309363 A1
(43) Pub. Date: Dec. 22, 2011

(54) ACTIVE MATRIX SUBSTRATE, LIQUID CRYSTAL DISPLAY APPARATUS HAVING THE SAME, AND METHOD FOR MANUFACTURING ACTIVE MATRIX SUBSTRATE

(75) Inventor: Katsunori Misaki, Osaka-shi (JP)

(73) Assignee: SHARP KABUSHIKI KAISHA, OSAKA (JP)

(21) Appl. No.: 13/201,152

(22) PCT Filed: Feb. 4, 2010
(86) PCT No.: PCT/JP2010/000667

§ 371 Date: Aug. 11, 2011

(30) Foreign Application Priority Data
Apr. 10, 2009 (JP) 2009-095525

(51) Int. Cl. H01L 33/16; H01L 29/786

(52) U.S. Cl. 257/59; 438/34; 257/E33.004; 257/E29.273

(57) ABSTRACT

A gate electrode is provided on a layered structure formed by successively stacking a conductive layer and an insulating layer. A storage capacitor includes a lower electrode formed in a same layer and made of a same material as the conductive layer, a dielectric layer provided on the lower electrode, formed in a same layer and made of a same material as the insulating layer, and an upper electrode formed in a same layer and made of a same material as the gate electrode to overlap the lower electrode with the dielectric layer sandwiched therebetween. A contact hole for connection to the storage capacitor is continuously formed in the interlayer and gate insulating films. The dielectric layer and the upper electrode are formed to have a lower conductive layer forming the lower electrode partially exposed from the dielectric layer, the upper electrode, and the interlayer and gate insulating films.

### TECHNICAL FIELD

The present disclosure relates to active matrix substrates, liquid crystal display devices including active matrix substrates, and methods for fabricating active matrix substrates.

### BACKGROUND ART

A liquid crystal display device driven with an active matrix drive scheme is configured such that a thin film transistor (hereinafter referred to as a TFT) is provided for each pixel, which is a minimum unit constituting an image, and a signal voltage is applied for each pixel selected through a TFT, thus displaying a desired image. In the liquid crystal display device, a storage capacitor for storing a signal voltage while a TFT is off is also provided for each pixel.

The storage capacitor includes upper and lower electrodes which are opposed to each other with a dielectric layer sandwiched therebetween, and is formed on an active matrix substrate, together with a TFT and other components, in order to simplify fabrication processes and reduce a fabrication cost. For example, in the case of a bottom-gate TFT, a lower electrode is formed concurrently with a gate electrode, a dielectric layer is formed concurrently with a gate insulating film, and an upper electrode is formed concurrently with a source electrode and a drain electrode.

As described above, in the case of forming a storage capacitor concurrently with a TFT, an upper electrode and a lower electrode are respectively made of the same non-transmissive metal materials as those of electrodes constituting the TFT. In this structure, a region provided with the storage capacitor is non-transmissive, and thus, causes a decrease in the aperture ratio of a pixel. Since the gate insulating film is used as a dielectric layer of the storage capacitor, the thickness of the dielectric layer is set at a value large enough to allow the gate insulating film to have a sufficient dielectric strength in the TFT. Thus, to form a storage capacitor having a predetermined capacitance, the areas of the upper electrode and the lower electrode need to be larger than predetermined values according to the thickness of the gate insulating film. Accordingly, when the pixel size decreases with an increase in definition of pixels, the storage capacitor occupies a larger area in each pixel, thereby decreasing the aperture ratio of the pixel. To solve this problem, configurations of storage capacitors having predetermined capacitances even with decreases in the areas of the upper and lower electrodes have been proposed to date.

For example, PATENT DOCUMENT 1 proposes a configuration in which a gate insulating film on a lower electrode of a storage capacitor is removed by etching, and a dielectric layer of the storage capacitor is formed on the lower electrode, as a component different from the gate insulating film. This patent shows that the area of the storage capacitor can be reduced relative to the area of the pixel electrode by reducing the thickness of the dielectric layer of the storage capacitor or increasing the dielectric constant of the dielectric layer to increase the capacitance of the storage capacitor per a unit area.

### CITATION LIST

### Patent Document

PATENT DOCUMENT 1: Japanese Patent Publication No. 2001-13520

### SUMMARY OF THE INVENTION

### Technical Problem

A configuration in which a gate insulating film on a lower electrode is removed by etching and a dielectric layer of a storage capacitor is formed on the lower electrode, as a component different from the gate insulating film as described in PATENT DOCUMENT 1, however, requires an additional photomask for forming a resist layer, as a mask for etching, on the gate insulating film, and also requires processes including resist application, light exposure, and development, to form the resist layer. These requirements greatly increase the number of fabrication process steps, and therefore, room for improvement remains in this configuration.

It is therefore an object of the present disclosure to reduce an increase in the number of fabrication process steps and a decrease in the aperture ratio of a pixel with a storage capacitor having a desired capacitance.

### Solution to the Problem

In order to achieve the above object, the present disclosure shows a configuration in which a dielectric layer of a storage capacitor is formed as a component different from a gate insulating film with an increase in the number of fabrication process steps suppressed.

Specifically, an active matrix substrate includes: a thin film transistor; a storage capacitor; an interlayer insulating film overlapping the thin film transistor and the storage capacitor; and a pixel electrode provided on the interlayer insulating film, and electrically connected to the thin film transistor and the storage capacitor via contact holes formed in the interlayer insulating film, wherein the thin film transistor includes a gate electrode, a gate insulating film covering the gate electrode, and a drain electrode provided on the gate insulating film and electrically connected to the pixel electrode, the gate electrode is provided on a layered structure formed by successively stacking a conductive layer and an insulating layer, the storage capacitor includes a lower electrode formed in a same layer and made of a same material as the conductive layer, a dielectric layer provided on the lower electrode, formed in a same layer and made of a same material as the insulating layer, and an upper electrode formed in a same layer and made of a same material as the gate electrode to overlap the lower electrode with the dielectric layer sandwiched therebetween, the contact hole for electrical connection to the storage capacitor is continuously formed in the interlayer insulating film and the gate insulating film, and the dielectric layer, the upper electrode, the interlayer insulating film, and the gate insulating film are formed such that a lower conductive layer forming the lower electrode is partially exposed from the dielectric layer, the upper electrode, the interlayer insulating film, and the gate insulating film.

In the configuration described above, the gate electrode is provided on the layered structure formed by successively stacking the conductive layer and the insulating layer, and the dielectric layer forming the storage capacitor is formed in the same layer and made of the same material as the insulating layer of the layered structure, and is provided as a component different from the gate insulating film. This configuration enables the thickness and the material of the dielectric layer to be arbitrarily selected. Accordingly, the dielectric layer of the storage capacitor can be made thin, or made of a material having a relatively high dielectric constant, thus increasing the capacitance of the storage capacitor per a unit area. As a result, it is possible to form a storage capacitor having a predetermined capacitance even with decreases in the areas of the upper electrode and the lower electrode. That is, it is possible to reduce the area of the storage capacitor, while maintaining a predetermined capacitance thereof.

In the case of fabricating an active matrix substrate as described above, a conductive film, an insulating film, and a conductive film are successively formed, and are patterned by photolithography at a time, thereby concurrently forming a gate electrode located on a layered structure, a lower conductive layer forming a lower electrode, an insulating layer for forming a dielectric layer, and an upper conductive layer for forming an upper electrode. Thereafter, a gate insulating film and an interlayer insulating film are formed, and the interlayer insulating film, the gate insulating film, the insulating layer, and the upper conductive layer are patterned by photolithography at a time, thereby forming contact holes for connections to the drain electrode and the storage capacitor, respectively, and also forming an upper electrode out of the upper conductive layer, and a dielectric layer out of the insulating layer. In this manner, a storage capacitor including the upper electrode, the dielectric layer, and a lower electrode made of a portion of the lower conductive layer overlapping the upper electrode and the dielectric layer can be formed. This structure enables a storage capacitor including a dielectric layer as a component different from a gate insulating film to be formed without an additional photomask.

With the structure described above, an increase in the number of fabrication process steps and a decrease in the aperture ratio of pixels can be reduced, and the storage capacitor having a desired capacitance can be obtained.

Preferably, the thin film transistor includes a semiconductor layer connected to the drain electrode and overlapping the gate electrode with the gate insulating film sandwiched therebetween, an etching stopper layer is provided between the interlayer insulating film and the gate insulating film, is formed in a same layer and made of a same material as the semiconductor layer, and overlaps the upper electrode, a connecting electrode is provided on the interlayer insulating film, and is formed as a component different from the pixel electrode, a contact hole for electrically connecting the connecting electrode and the storage capacitor is provided in the interlayer insulating film and the gate insulating film, and is formed as a component different from the contact hole for electrically connecting the pixel electrode and the storage capacitor, one of the contact hole for electrically connecting the pixel electrode and the storage capacitor or the contact hole for electrically connecting the connecting electrode and the storage capacitor serves as a first contact hole for connection to the upper electrode, and the other contact hole serves as a second contact hole for connection to the lower conductive layer, and the first contact hole is also formed in the etching stopper layer.

With the configuration described above, in fabricating the active matrix substrate, the interlayer insulating film and the gate insulating film are patterned by photolithography at a time. Accordingly, in the case of forming the first contact hole for connection to the upper electrode and the second contact hole for connection to the lower conductive layer at a time, etching on the region where the first contact hole is to be formed is inhibited by the etching stopper layer, resulting in that etching on the region where the first contact hole is to be formed is performed more slowly than etching on the region where the second contact hole is to be formed. This structure can reduce damage on the storage capacitor caused by etching on the upper electrode and the dielectric layer. Since the etching stopper layer is formed in the same layer and made of the same material as the semiconductor layer forming the thin film transistor, the etching stopper layer can be formed concurrently with formation of the semiconductor layer. In this manner, an increase in the number of fabrication process steps for forming the etching stopper layer can be reduced.

Preferably, a gate line connected to the gate electrode is provided, an etching stopper layer is provided between the interlayer insulating film and the gate insulating film, is formed in a same layer and made of a same material as the semiconductor layer, and overlaps a terminal of the gate line, a gate connecting electrode is provided on the interlayer insulating film, a third contact hole for connecting the gate connecting electrode and the terminal of the gate line is formed in the interlayer insulating film and the gate insulating film, and the third contact hole is also formed in the etching stopper layer overlapping the terminal of the gate line.

In the configuration described above, in fabricating the active matrix substrate, the interlayer insulating film and the gate insulating film are patterned by photolithography at a time. Accordingly, in the case of forming the third contact hole for connection to the terminal of the gate line and the second contact hole for connection to the lower conductive layer at a time, etching on the region where the third contact hole is to be formed is inhibited by the etching stopper layer, resulting in that etching on the region where the third contact hole is to be formed is performed more slowly than etching on the region where the second contact hole is to be formed. This structure can reduce damage on the terminal of the gate line caused by etching. Since the etching stopper layer overlapping the terminal of the gate line is also formed in the same layer and made of the same material as the semiconductor layer forming the thin film transistor, the etching stopper layer can be formed concurrently with formation of the semiconductor layer. In this manner, an increase in the number of fabrication process steps for forming the etching stopper layer can be reduced.

The upper electrode of the storage capacitor may be electrically connected to the pixel electrode via the contact hole.

The lower electrode of the storage capacitor may be electrically connected to the pixel electrode via the contact hole.

A liquid crystal display device according to the present disclosure includes: the active matrix substrate with the configuration described above; a counter substrate opposed to the active matrix substrate; and a liquid crystal layer provided between the active matrix substrate and the counter substrate.

In this liquid crystal display device, the active matrix substrate configured as described above is also effective.

A method for fabricating an active matrix substrate according to the present disclosure is a method for fabricating an active matrix substrate including a thin film transistor, a storage capacitor, an interlayer insulating film overlapping the thin film transistor and the storage capacitor, and a pixel electrode provided on the interlayer insulating film, and electrically connected to the thin film transistor and the storage capacitor via contact holes formed in the interlayer insulating film, the thin film transistor including a gate electrode, a gate insulating film covering the gate electrode, and a drain electrode provided on the gate insulating film and electrically connected to the pixel electrode. This method includes: a multilayer film formation step of successively stacking a first conductive film, an insulating film, and a second conductive film on a substrate, thereby forming a multilayer film; a multilayer film patterning step of patterning the first conductive film, the insulating film, and the second conductive film at a time, thereby forming the gate electrode out of the second conductive film, a lower conductive layer out of the first conductive film, an insulating layer out of the insulating film, and an upper conductive layer out of the second conductive film such that the lower conductive layer, the insulating layer, and the upper conductive layer overlap; a gate insulating film formation step of forming the gate insulating film such that the gate insulating film covers the gate electrode and the upper conductive layer; a drain electrode formation step of forming the drain electrode on the gate insulating film; an interlayer insulating film formation step of forming the interlayer insulating film such that the interlayer insulating film covers the drain electrode and overlaps the upper conductive layer with the gate insulating film sandwiched therebetween; a contact hole formation step of patterning the interlayer insulating film, the gate insulating film, the upper conductive layer, and the insulating layer at a time, thereby forming a contact hole for electrical connection to the drain electrode in the interlayer insulating film and a contact hole for electrical connection to the storage capacitor in the interlayer insulating film and the gate insulating film, forming an upper electrode out of the upper conductive layer and a dielectric layer overlapping the upper electrode out of the insulating layer with the lower conductive layer partially exposed, to form the storage capacitor including the upper electrode, the dielectric layer, and a lower electrode made of a portion of the lower conductive layer overlapping the upper electrode and the dielectric layer; and a pixel electrode formation step of forming the pixel electrode on the interlayer insulating film such that the pixel electrode is electrically connected to the drain electrode and the storage capacitor via the contact holes.

In the method described above, it is possible to form a storage capacitor including a dielectric layer as a component different from a gate insulating film without an additional photomask. In addition, the dielectric layer forming the storage capacitor is formed as a component different from the gate insulating film. This process enables the thickness and the material of the dielectric layer of the storage capacitor to be arbitrarily selected. Accordingly, the dielectric layer can be made thin, or made of a material having a relatively high dielectric constant, thus increasing the capacitance of the storage capacitor per a unit area. As a result, it is possible to form a storage capacitor having a predetermined capacitance even with decreases in the areas of the upper electrode and the lower electrode. That is, it is possible to reduce the area of the storage capacitor, while maintaining a predetermined capacitance thereof. Consequently, an increase in the number of fabrication process steps and a decrease in the aperture ratio of pixels can be reduced, and a storage capacitor having a desired capacitance can be obtained.

In the contact hole formation step, a first contact hole for connection to the upper electrode and a second contact hole for connection to the lower conductive layer may be formed in the interlayer insulating film and the gate insulating film. In addition, in the pixel electrode formation step, the pixel electrode may be formed to be electrically connected to the storage capacitor via one of the first contact hole or the second contact hole, and a connecting electrode may be formed to be electrically connected to the storage capacitor via the other contact hole.

### Advantages of the Invention

According to the present disclosure, concurrently with formation of a gate electrode, a lower conductive layer, an insulating layer, and an upper conductive layer are formed to overlap. Further, concurrently with formation of contact holes in an interlayer insulating film and a gate insulating film, the insulating layer and the upper conductive layer are patterned, thereby forming a dielectric layer and an upper electrode forming a storage capacitor out of the insulating layer and the upper conductive layer, respectively. With this process, the dielectric layer of the storage capacitor is provided as a component different from the gate insulating film. Accordingly, an increase in the number of fabrication process steps and a decrease in the aperture ratio of pixels can be reduced, a storage capacitor having a desired capacitance can be obtained. As a result, display quality can be improved with simplified fabrication processes and a reduced fabrication cost.

### BRIEF DESCRIPTION OF THE DRAWINGS

FIG. 1 is a plan view schematically illustrating a liquid crystal display device according to a first embodiment.

FIG. 2 is a view schematically illustrating a cross section taken along line II-II in FIG. 1.

FIG. 3 is a plan view schematically illustrating a configuration of a pixel and terminals in an active matrix substrate of the first embodiment.

FIG. 4 is a cross-sectional view schematically illustrating a configuration of a pixel and terminals in the active matrix substrate of the first embodiment.

FIG. 5 is a cross-sectional view showing a multilayer film formation step in a method for fabricating an active matrix substrate according to the first embodiment.

FIG. 6 is a cross-sectional view showing a multilayer film patterning step in the method for fabricating an active matrix substrate of the first embodiment.

FIG. 7 is a cross-sectional view showing a gate insulating film formation step in the method for fabricating an active matrix substrate of the first embodiment.

FIG. 8 is a cross-sectional view showing a state in which a semiconductor layer portion and an etching stopper layer are formed in a drain electrode formation step in the method for fabricating an active matrix substrate of the first embodiment.

FIG. 9 is a cross-sectional view showing a state in which a semiconductor layer, a source electrode, and a drain electrode are formed in the drain electrode formation step in the method for fabricating an active matrix substrate of the first embodiment.

FIG. 10 is a cross-sectional view showing an interlayer insulating film formation step in the method for fabricating an active matrix substrate of the first embodiment.

FIG. 11 is a cross-sectional view showing a contact hole formation step in the method for fabricating an active matrix substrate of the first embodiment.

FIG. 12 is a plan view schematically illustrating a configuration of a pixel and terminals in an active matrix substrate according to a second embodiment.

FIG. 13 is a cross-sectional view schematically illustrating a configuration of a pixel and terminals in the active matrix substrate of the second embodiment.

FIG. 14 is a cross-sectional view showing a multilayer film patterning step in a method for fabricating an active matrix substrate according to the second embodiment.

FIG. 15 is a cross-sectional view showing a drain electrode formation step in the method for fabricating an active matrix substrate of the second embodiment.

FIG. 16 is a cross-sectional view showing a contact hole formation step in the method for fabricating an active matrix substrate of the second embodiment.

### DESCRIPTION OF EMBODIMENTS

Embodiments of the present disclosure will be described hereinafter with reference to the drawings. The present disclosure is not limited to the following embodiments.

### First Embodiment

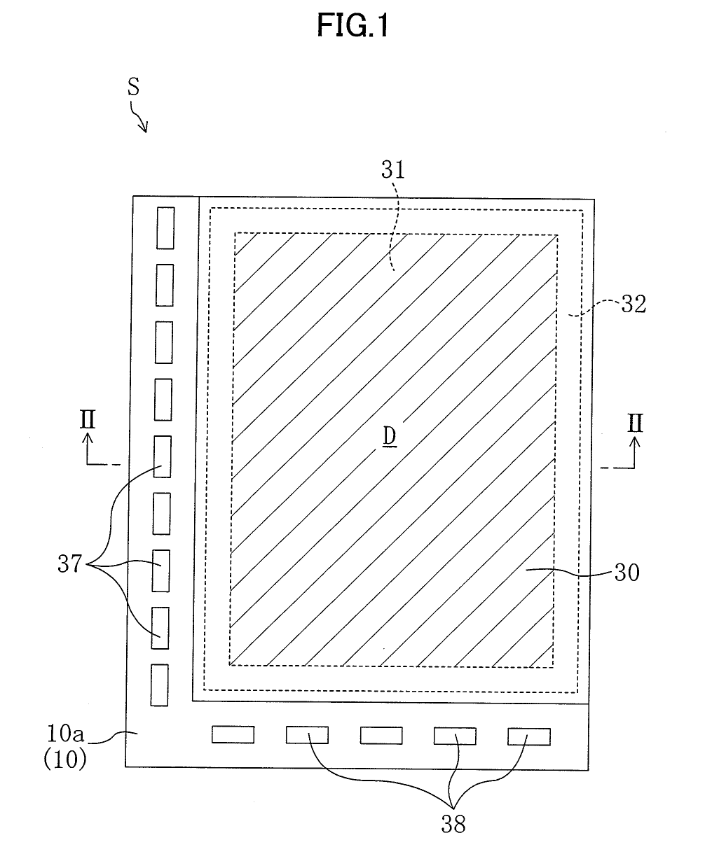

FIGS. 1 to 11 illustrate an active matrix substrate, a liquid crystal display device including the active matrix substrate, and a method for fabricating an active matrix substrate according to a first embodiment of the present disclosure.

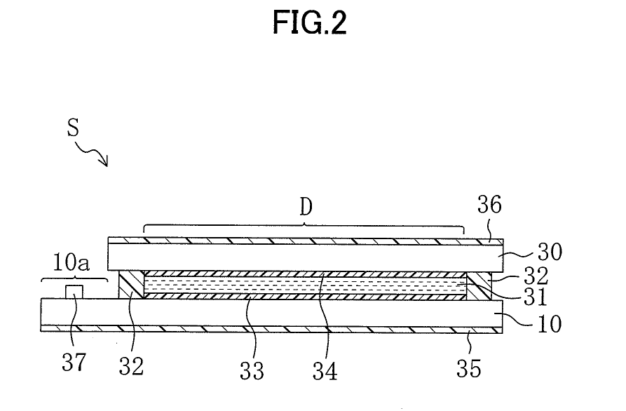

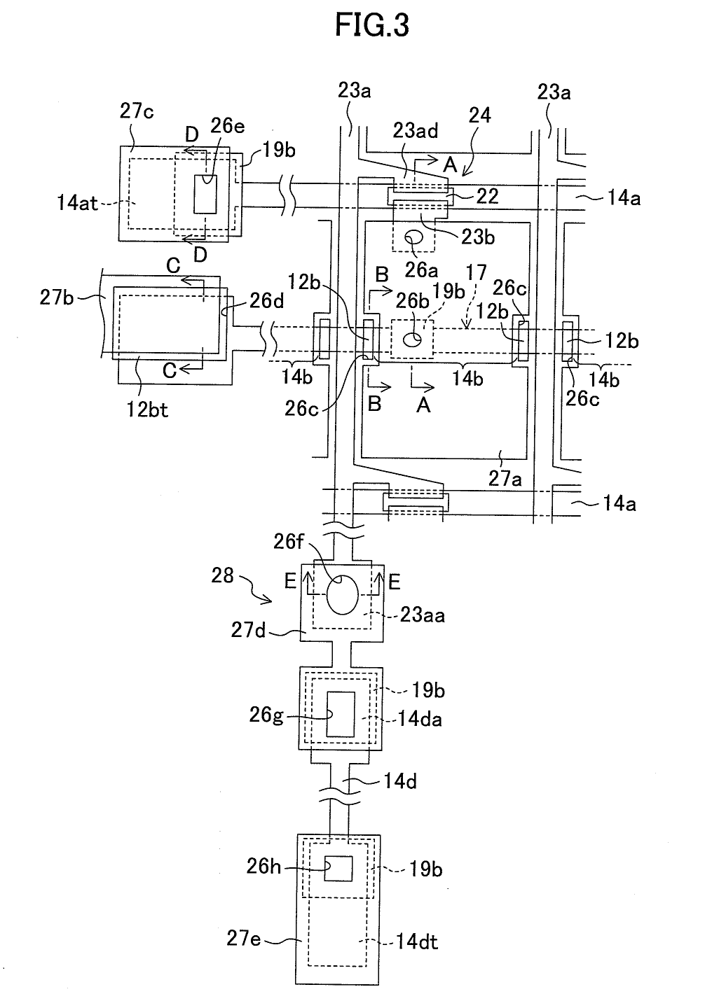

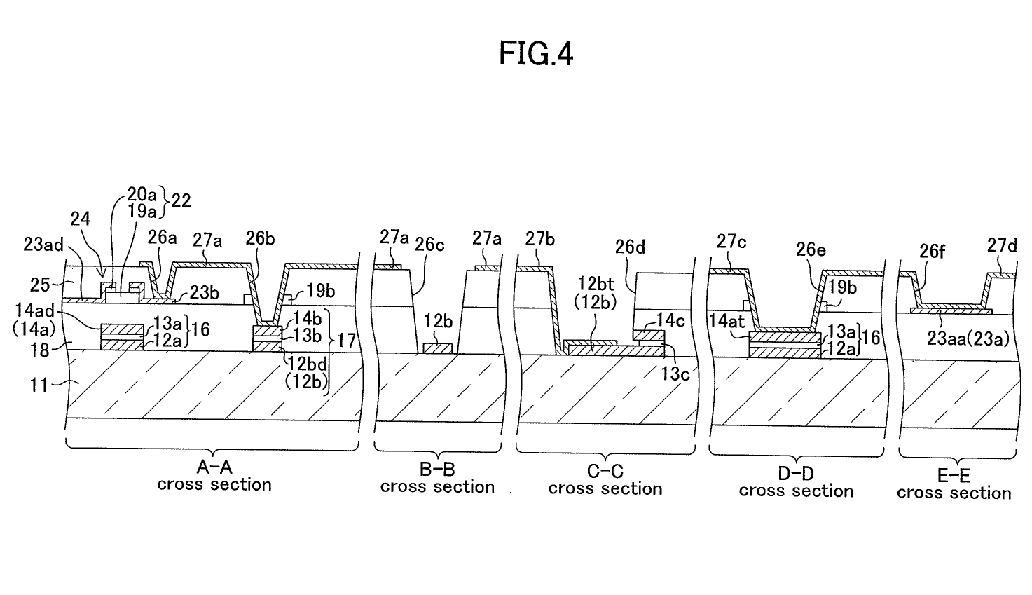

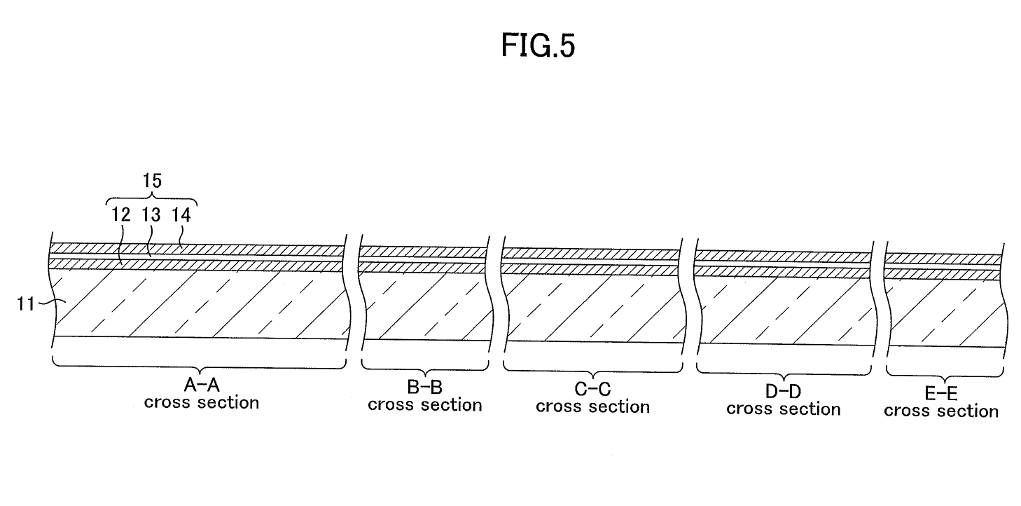

FIG. 1 is a plan view schematically illustrating a liquid crystal display device S according to this embodiment. FIG. 2 is a cross-sectional view schematically illustrating the liquid crystal display device S taken along line II-II in FIG. 1. FIG. 3 is a plan view schematically illustrating a configuration of a pixel and terminals in an active matrix substrate 10. FIG. 4 is a cross-sectional view schematically illustrating a configuration of a pixel and terminals in the active matrix substrate 10. FIGS. 5 to 11 are views for describing a method for fabricating an active matrix substrate 10 according to this embodiment, which will be described later. In FIG. 1, a polarizing plate is not shown for simplicity of description. FIG. 4 illustrates cross-sections taken along lines A-A, B-B, C-C, D-D, and E-E in FIG. 3 in this order from the left to the right in the drawing sheet.

<Configuration of Liquid Crystal Display Device S>

As illustrated in FIGS. 1 and 2, the liquid crystal display device S includes: the active matrix substrate 10 and a counter substrate 30 which are opposed to each other; a liquid crystal layer 31 provided between the active matrix substrate 10 and the counter substrate 30; and a sealing material 32 for bonding the active matrix substrate 10 and the counter substrate 30 together and sealing the liquid crystal layer 31.

Each of the active matrix substrate 10 and the counter substrate 30 is formed in the shape of a rectangle, for example. As illustrated in FIG. 2, alignment films 33 and 34 are respectively provided on the surfaces of the active matrix substrate 10 and the counter substrate 30 which are located on a side of the liquid crystal layer 31, and polarizing plates 35 and 36 are respectively provided on the opposite sides of the active matrix substrate 10 and the counter substrate 30 from the liquid crystal layer 31. The liquid crystal layer 31 is made of, for example, a nematic liquid crystal material having an electrooptical property. As illustrated in FIG. 1, the sealing material 32 is formed in the shape of a rectangular frame extending along the sides of the counter substrate 30, for example.

The liquid crystal display device S has a display region D in which the active matrix substrate 10 and the counter substrate 30 overlap each other and which is used to display an image inside the sealing material 32. At the outside of the display region D, the active matrix substrate 10 projects from the counter substrate 30 to be in the shape of L, for example, and form a mounting portion 10a.

The display region D is rectangular, for example, and is made of pixels, each of which is a minimum unit of an image and which are arranged in a matrix. On the other hand, on the mounting portion 10a, a plurality of gate-driver integrated circuits (hereinafter referred to as IC) chips 37 are mounted with an anisotropic conductive film (hereinafter referred to as ACF) interposed therebetween along one side (i.e., the inner left side in FIG. 1), and a plurality of source-driver IC chips 38 are mounted with an ACF interposed therebetween along another side (i.e., the inner bottom side in FIG. 1).

<Configuration of Active Matrix Substrate 10>

As illustrated in FIGS. 3 and 4, in the display region D, the active matrix substrate 10 includes: a plurality of gate lines 14a provided in parallel with each other on an insulating substrate 11; a plurality of storage capacitor lines (a lower conductive layer) 12b which are parallel with each other and each of which extends between associated two of the gate lines 14a; a gate insulating film 18 overlapping the gate lines 14a and the storage capacitor lines 12b; and a plurality of source lines 23a which are provided on the gate insulating film 18, are parallel with each other, and are orthogonal to the gate lines 14a. The gate lines 14a and the source lines 23a are arranged to form a lattice pattern as an overall layout, and define pixels. The storage capacitor lines 12b extend across a plurality of pixels in a direction in which the gate lines 14a extend.

The active matrix substrate 10 further includes: TFTs 24; storage capacitors 17; an interlayer insulating film 25 overlying the TFTs 24 and the storage capacitors 17; and pixel electrodes 27a which are provided in a matrix on the interlayer insulating film 25 and are associated with respective pixels. One of the TFTs 24 and one of the storage capacitors 17 are provided in each of the pixels.

As illustrated in FIG. 4 (specifically in an A-A cross section), each of the TFTs 24 is a bottom-gate TFT, and includes: a gate electrode 14ad which is part of the gate lines 14a; a gate insulating film 18 covering the gate electrode 14ad; an island-shaped semiconductor layer 22 overlapping the gate electrode 14ad with the gate insulating film 18 interposed therebetween; and a source electrode 23ad and a drain electrode 23b which are connected to the semiconductor layer 22 and are separate from each other.

The gate electrode 14ad (the gate line 14a) are provided on a layered structure 16 formed by successively stacking a metal layer (a conductive layer) 12a and an insulating layer 13a. The semiconductor layer 22 is formed by successively stacking an intrinsic amorphous silicon layer 19a and an n⁺ amorphous silicon layer 20a. The n⁺ amorphous silicon layer 20a is partially removed at a middle portion thereof to expose the intrinsic amorphous silicon layer 19a therein, and is divided into two in the direction along the width of the gate electrode 14ad (i.e., the lateral direction in the drawing sheet of FIG. 4). The exposed portion of the intrinsic amorphous silicon layer 19a forms a channel portion. As illustrated in FIG. 3, the source electrode 23ad projects from the side of each of the source lines 23a, and overlaps one of the two divided portions of the n⁺ amorphous silicon layer 20a. The drain electrode 23b overlaps the other portion of the n⁺ amorphous silicon layer 20a, and is connected to the pixel electrode 27a via a contact hole 26a formed in the interlayer insulating film 25.

As shown in FIG. 4 (specifically in the A-A cross section), each of the storage capacitors 17 includes: a lower electrode 12bd as part of the storage capacitor line 12b; a dielectric layer 13b provided on the lower electrode 12bd; and an upper electrode 14b overlapping the lower electrode 12bd with the dielectric layer 13b sandwiched therebetween. The lower electrode 12bd is formed in the same layer and made of the same material as the metal layer 12a. The dielectric layer 13b is formed in the same layer and made of the same material as the insulating layer 13a. The upper electrode 14b is formed in the same layer and made of the same material as the gate electrode 14ad.

The upper electrode 14b of the storage capacitor 17 is connected to the pixel electrode 27a via a contact hole (a first contact hole) 26b continuously formed in the gate insulating film 18 and the interlayer insulating film 25. The contact hole 26b is formed through an etching stopper layer 19b which is provided between the gate insulating film 18 and the interlayer insulating film 25 and overlaps the upper electrode 14b. The etching stopper layer 19b is formed in the same layer and made of the same material as the intrinsic amorphous silicon layer 19a of the semiconductor layer 22. As illustrated in FIG. 4 (specifically in a B-B cross section), each upper electrode 14b is removed to be divided together with the dielectric layer 13b in a hole 26c formed at both sides of each of the pixel electrodes 27a in the lateral direction in the drawing sheet of FIG. 3, and is electrically separated from other upper electrodes 14b. The hole 26c is also continuously formed in the interlayer insulating film 25 and the gate insulating film 18. In this manner, the dielectric layer 13b and the upper electrode 14b are formed such that the storage capacitor lines 12b are partially exposed.

Each of the storage capacitor lines 12b extends to a region where the sealing material 32 is provided. Each end of the storage capacitor line 12b constitutes a common terminal 12bt shown in FIG. 3 and FIG. 4 (specifically, a C-C cross section). The common terminal 12bt is exposed from the insulating layer 13c and the metal layer 14c provided on the storage capacitor line 12b, and is connected to a common connecting electrode 27b on the interlayer insulating film 25 via a contact hole (a second contact hole) 26d continuously formed in the interlayer insulating film 25 and the gate insulating film 18. The common connecting electrode 27b is electrically connected to a common electrode of the counter substrate 30, which will be described later, by so-called common transfer.

Each of the gate lines 14a is extended to the mounting portion 10a to reach a region where the gate-driver IC chips 37 are to be mounted, and the extended end portion forms a gate terminal 14at shown in FIG. 3 and FIG. 4 (specifically, in a D-D cross section). The gate terminal 14at is connected to a gate connecting electrode 27c on the interlayer insulating film 25 via a contact hole (a third contact hole) 26e continuously formed in the interlayer insulating film 25 and the gate insulating film 18. The contact hole 26e is also formed through the etching stopper layer 19b which is provided between the gate insulating film 18 and the interlayer insulating film 25 and overlaps the gate terminal 14at. The gate connecting electrode 27c forms an electrode for connection to the gate-driver IC chip 37.

As illustrated in FIG. 3, each of the source lines 23a is extended to the mounting portion 10a to reach a region where a source-driver IC chip 38 is to be mounted via an interconnection portion 28 for interconnection to a lead line 14d formed in the same layer as the gate lines 14a, and an end of the extended interconnection portion 28 forms a source terminal 14dt. In the same manner as the gate line 14a , the lead line 14d is provided on the layered structure 16.

The interconnection portion 28 is provided on a region where the sealing material 32, for example, is formed. As illustrated in FIG. 4 (specifically in an E-E cross section), in the interconnection portion 28, a lead end 23aa provided in the same layer as the source line 23a in the display region D is connected to an interconnection electrode 27d provided on the interlayer insulating film 25 via a contact hole 26f formed in the interlayer insulating film 25. The interconnection electrode 27d is connected to one end 14da of the lead line 14d via a contact hole 26g continuously formed in the interlayer insulating film 25 and the gate insulating film 18 and illustrated in FIG. 3. The contact hole 26g is also formed through the etching stopper layer 19b provided between the gate insulating film 18 and the interlayer insulating film 25 and overlapping the end 14da of the lead line 14d.

The source terminal 14dt made of the other end of the lead line 14d is connected to a source connecting electrode 27e provided on the interlayer insulating film 25 via a contact hole 26h continuously formed in the interlayer insulating film 25 and the gate insulating film 18. The contact hole 26h is also formed through the etching stopper layer 19b provided between the gate insulating film 18 and the interlayer insulating film 25 and overlapping the source terminal 14dt. The source connecting electrode 27e forms an electrode for connection to the source-driver IC chip 38.

<Configuration of Counter Substrate 30>

Although not shown, the counter substrate 30 includes: a black matrix provided on the insulating substrate and formed in the shape of a lattice corresponding to the shape formed by the gate lines 14a and the source lines 23a; color filters of a plurality of colors including a red layer, a green layer, and a blue layer, and periodically arranged between the lattice of the black matrix; a common electrode covering the black matrix and the color filters; and a columnar photo spacer provided on the common electrode.

<Operation of Liquid Crystal Display Device S>

In the liquid crystal display device S with the foregoing configuration, in each of the pixels, when a gate signal is sent from the gate-driver IC chip 37 to the gate electrode 14ad through the gate line 14a to turn the TFT 24 on, a source signal is sent from the source-driver IC chip 38 to the source electrode 23ad through the source line 23a so that a predetermined amount of charge is written in the pixel electrode 27a through the semiconductor layer 22 and the drain electrode 23b. At this time, a potential difference occurs between the pixel electrode 27a of the active matrix substrate 10 and the common electrode of the counter substrate 30, thereby applying a predetermined voltage to the liquid crystal layer 31. When the TFT 24 is off, a storage capacitance formed between the lower electrode 12bd and the upper electrode 14b in the storage capacitor 17 reduces a decrease in the voltage written in the pixel electrode 27a. In the liquid crystal display device S, the alignment state of liquid crystal molecules is changed for each pixel according to the level of the voltage applied to the liquid crystal layer 31, thereby adjusting the light transmittance of the liquid crystal layer 31 to display a desired image.

—Fabrication Method—

Referring now to FIGS. 5 to 11, a method for fabricating the active matrix substrate 10 and the liquid crystal display device S will be described.

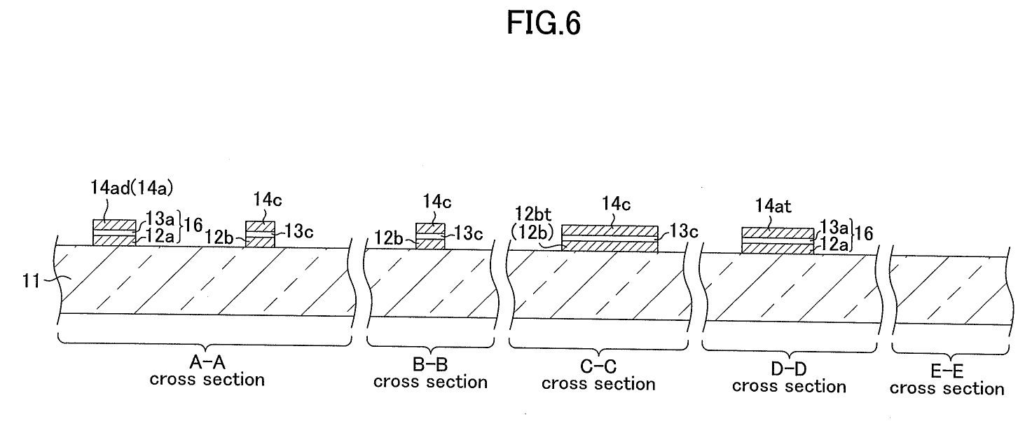

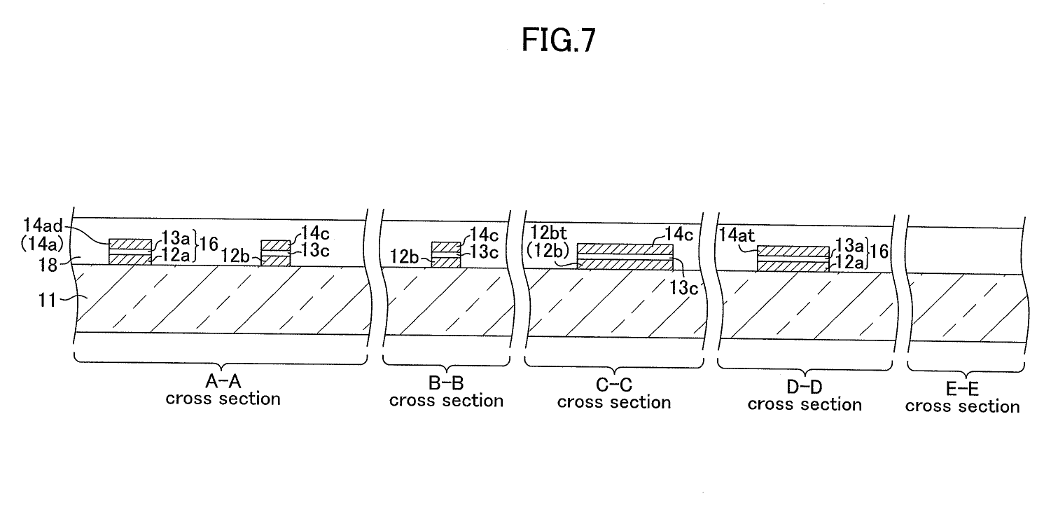

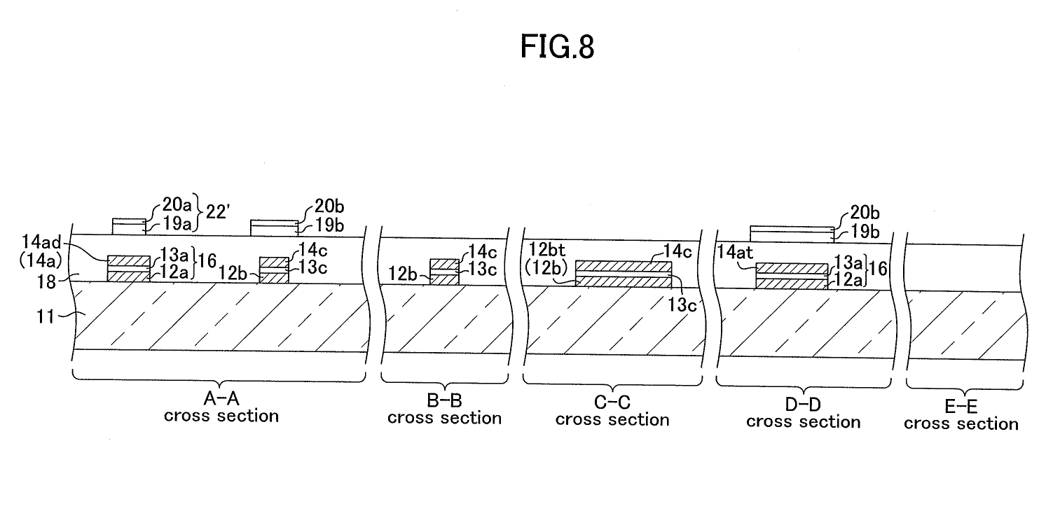

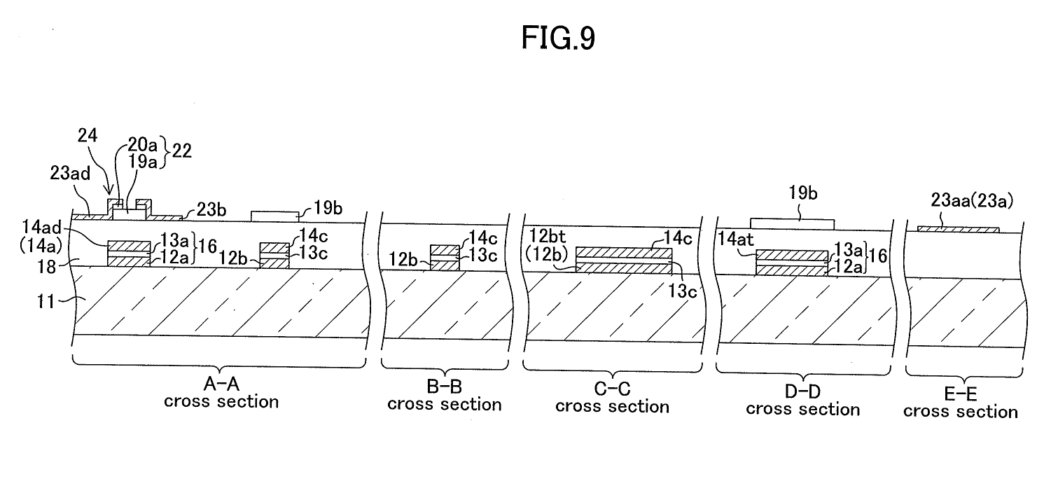

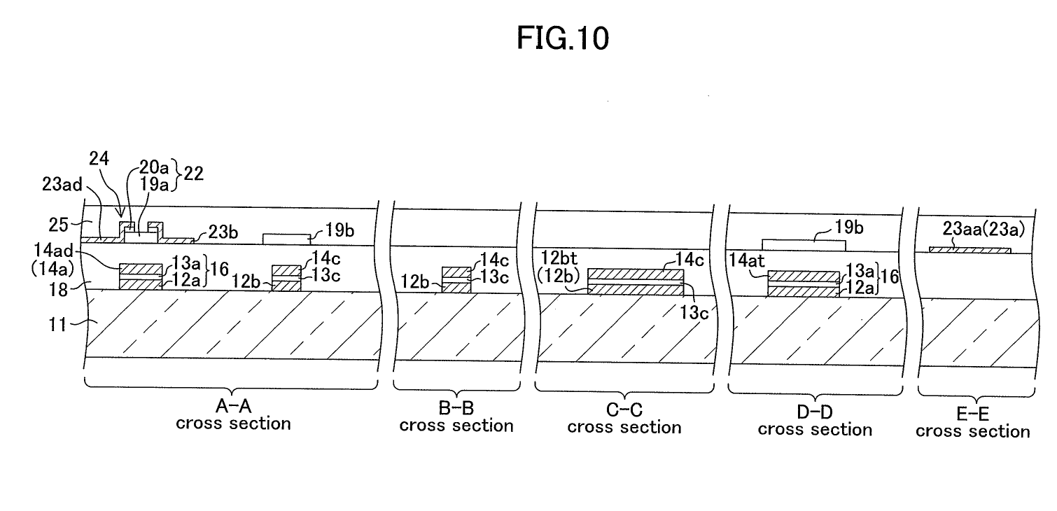

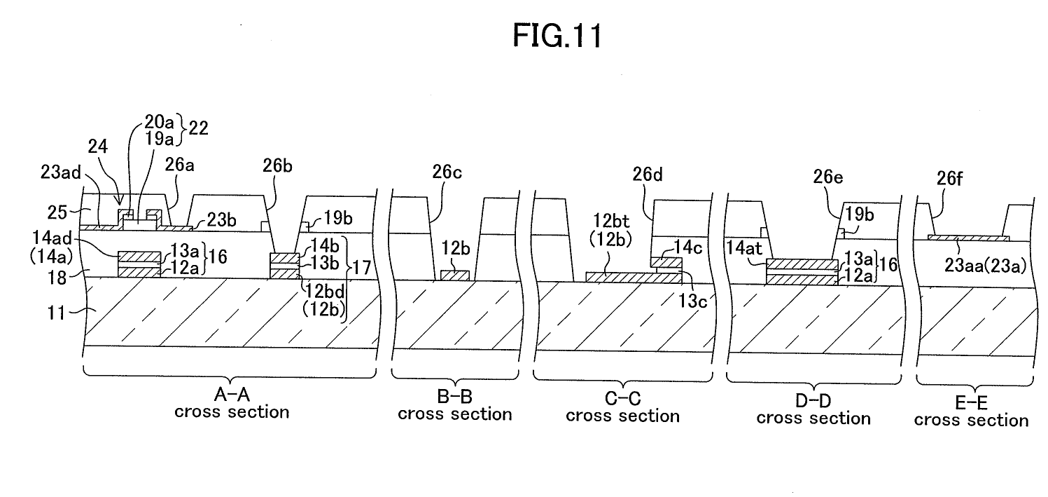

FIG. 5 is a cross-sectional view illustrating a state in which a multilayer film 15 is formed on an insulating substrate 11. FIG. 6 is a cross-sectional view illustrating a state in which the multilayer film 15 is patterned such that a storage capacitor line 12b, an insulating layer 13c, and a conductive layer 14c for forming a storage capacitor 17 and a gate electrode 14ad are formed. FIG. 7 is a cross-sectional view illustrating a state in which a gate insulating film 18 is formed. FIG. 8 is a cross-sectional view illustrating a state in which a semiconductor layer portion 22′ and an etching stopper layer 19b are formed. FIG. 9 is a cross-sectional view illustrating a state in which a semiconductor layer 22, a source electrode 23ad, and a drain electrode 23b are formed. FIG. 10 is a cross-sectional view illustrating a state in which an interlayer insulating film 25 is formed. FIG. 11 is a cross-sectional view illustrating a state in which the interlayer insulating film 25 and the gate insulating film 18 are patterned so that contact holes 26a, 26b, 26d, 26e, and 26f and a hole 26c are formed. FIGS. 5 to 11 respectively illustrate portions associated with the cross sections (i.e., the A-A cross section, the B-B cross section, the C-C cross section, the D-D cross section, and the E-E cross section) in FIG. 4. FIGS. 6, 8, 9, and 11 do not show resist layers.

A method for fabricating a liquid crystal display device S according to this embodiment includes an active matrix substrate formation step, a counter substrate formation step, a bonding step, and a mounting step.

<Active Matrix Substrate Formation Step>

The active matrix substrate formation step includes: a multilayer film formation step; a multilayer film patterning step; a gate insulating film formation step; a drain electrode formation step; an interlayer insulating film formation step; a contact hole formation step; and a pixel electrode formation step.

<Multilayer Film Formation Step>

As illustrated in FIG. 5, a metal film 12 such as an aluminium film is formed by sputtering as a first conductive film over an insulating substrate 11 such as a glass substrate. Then, an insulating film 13 such as a silicon nitride film is formed by plasma chemical vapor deposition (CVD) over the metal film 12. Subsequently, a metal film 14 such as a titanium film is formed by sputtering as a second conductive film over the insulating film 13. In this manner, the metal film 12, the insulating film 13, and the metal film 14 are formed in this order, thereby forming a multilayer film 15.

<Multilayer Film Patterning Step>

The metal film 12, the insulating film 13, and the metal film 14 of the multilayer film 15 formed on the insulating substrate 11 through the multilayer film formation step are patterned at a time by a photolithography process in which etching is performed using, as a mask, a resist layer formed with a first photomask. In this manner, as illustrated in FIG. 6, a metal layer 12a is formed out of the metal film 12, an insulating layer 13a is formed out of the insulating film 13, and a gate line 14a and a gate electrode 14ad are formed out of the metal film 14 such that the metal layer 12a, the insulating layer 13a, and the gate line 14a including the gate electrode 14ad overlap. At the same time, a storage capacitor line 12b is formed out of the metal film 12, an insulating layer 13c is formed out of the insulating film 13, and a metal layer (an upper conductive layer) 14c is formed out of the metal film 14 such that the storage capacitor line 12b, the insulating layer 13c, and the metal layer 14c overlap. Accordingly, the gate line 14a and the gate electrode 14ad are formed on the layered structure 16 concurrently with formation of the storage capacitor line 12b, the insulating layer 13c, and the metal layer 14c for forming a storage capacitor 17. Thereafter, the resist layer used as a mask is removed by ashing. At this time, the insulating layer 13c and the metal layer 14c are formed over the entire storage capacitor line 12b.

<Gate Insulating Film Formation Step>

As illustrated in FIG. 7, a silicon nitride film, for example, is formed by plasma CVD over a substrate on which the gate line 14a, the gate electrode 14ad, and the storage capacitor line 12b, the insulating layer 13c, and the metal layer 14c for forming the storage capacitor 17 are formed through the multilayer film patterning step, thereby forming a gate insulating film 18 covering the gate electrode 14ad and the metal layer 14c.

<Drain Electrode Formation Step>

On the substrate on which the gate insulating film 18 is formed through the gate insulating film formation step, films such as an intrinsic amorphous silicon film and an n⁺ amorphous silicon film doped with, for example, phosphorus are consecutively formed by plasma CVD, thereby forming a semiconductor multilayer film. Then, the semiconductor multilayer film is patterned by a photolithography process in which etching is performed using, as a mask, a resist layer formed with a second photomask, thereby forming a semiconductor layer portion 22′ as a stack of the intrinsic amorphous silicon layer 19a and the n⁺ amorphous silicon layer 20a, and an etching stopper layer 19b on which the n⁺ amorphous silicon layer 20b is stacked, as illustrated in FIG. 8. Thereafter, the resist layer used as a mask is removed by ashing.

Next, over the substrate on which the semiconductor layer portion 22′ and the etching stopper layer 19b are formed, a titanium film and an aluminium film, for example, are successively formed by sputtering, thereby forming a metal multilayer film. The metal multilayer film is patterned by a photolithography process in which etching is performed using, as a mask, a resist layer formed with a third photomask, thereby forming a source line 23a, a source electrode 23ad, and a drain electrode 23b on the gate insulating film 18. Thereafter, the resist layer used as a mask is removed by ashing.

Then, the n⁺ amorphous silicon layer 20a in the semiconductor layer portion 22′ is etched using the source electrode 23ad and the drain electrode 23b as a mask, thereby patterning a channel portion to form a semiconductor layer 22 and a TFT 24 including the semiconductor layer 22, as illustrated in FIG. 9. At this time, the n⁺ amorphous silicon layer 20b on the etching stopper layer 19b is also removed by etching.

<Interlayer Insulating Film Formation Step>

As illustrated in FIG. 10, a silicon nitride film, for example, is formed by plasma CVD over the substrate on which the TFT 24 is formed through the drain electrode formation step, thereby forming an interlayer insulating film 25 covering the drain electrode 23b and overlapping the metal layer 14c with the gate insulating film 18 interposed therebetween.

<Contact Hole Formation Step>

The interlayer insulating film 25 formed through the interlayer insulating film formation step, the gate insulating film 18, the metal layer 14c, and the insulating layer 13c are patterned at a time by a photolithography process in which dryetching is performed with a fluorine-based gas such as CF₄ gas using, as a mask, a resist layer formed with a fourth photomask, thereby forming contact holes 26a, 26b, 26d, 26e, and 26f and a hole 26c at a time as illustrated in FIG. 11, and also forming other contact holes 26g and 26h at a time. In addition, at this time, the metal layer 14c and the insulating layer 13c in the hole 26c are removed so that the storage capacitor line 12b is partially exposed, thereby forming an upper electrode 14b out of the metal layer 14c, and a dielectric layer 13b overlapping the upper electrode 14b out of the insulating layer 13c. In this manner, a storage capacitor 17 including the upper electrode 14b, the dielectric layer 13b, and a lower electrode 12bd made of a portion of the storage capacitor line 12b where the upper electrode 14b and the dielectric layer 13b overlap each other, is formed together with the contact holes 26a, 26b, 26d, 26e, and 26f. Concurrently with the formation of the contact hole 26d, the insulating layer 13c and the metal layer 14c on a common terminal 12bt are removed, thereby exposing the common terminal 12bt. At this time, since the drain electrode 23b and the lead end 23aa of the source line 23a serve as en etching stopper, etching on the region where the contact holes 26a and 26f are to be formed is stopped when the drain electrode 23b and the lead end 23aa of the source line 23a are exposed. Etching on the regions where the contact holes 26b, 26e, 26g, and 26h are to be formed is inhibited by the etching stopper layer 19b, resulting in that etching on the regions where the contact holes 26b, 26e, 26g, and 26h are to be formed is performed more slowly than etching on the regions where the hole 26c and the contact hole 26d are to be formed. Accordingly, damage on the storage capacitor 17 caused by etching of the upper electrode 14b and the dielectric layer 13b, damage on the interconnection portion 28 caused by etching of the end 14da of the lead line 14d, damage on the terminals 14at and 14dt caused by etching are reduced. Thereafter, the resist layer used as a mask is removed by ashing.

<Pixel Electrode Formation Step>

An indium tin oxide (ITO) film, for example, is formed by sputtering over a substrate on which the contact holes 26a, 26b, 26d, 26e, 26f, 26g, and 26h and the hole 26c are formed through the contact hole formation step. Then, the ITO film is patterned by a photolithography process in which etching is performed using, as a mask, a resist layer formed with a fifth photomask, thereby forming a pixel electrode 27a, a common connecting electrode 27b, a gate connecting electrode 27c, an interconnection electrode 27d, and a source connecting electrode 27e. Thereafter, the resist layer used as a mask is removed by ashing.

In the manner described above, an active matrix substrate 10 can be fabricated.

<Counter Substrate Formation Step>

First, a negative acrylic photosensitive resin in which fine particles of, for example, carbon are dispersed is applied by spin coating onto the entire surface of the insulating substrate such as the glass substrate. Thereafter, the applied photosensitive resin is exposed to light with a photomask, and then is developed, thereby forming a black matrix.

Next, a negative acrylic photosensitive resin colored in red, green, or blue, for example, is applied onto the substrate on which the black matrix is formed. Thereafter, the applied photosensitive resin is exposed to light, and then is developed, thereby patterning the photosensitive resin. In this manner, the colored layer in a selected color (e.g., a red layer) is formed. Further, the same processes are repeated to form colored layers of other two colors (e.g., a green layer and a blue layer), thereby forming color filters.

Then, an ITO film, for example, is formed by sputtering over the substrate on which the color filters are formed, thereby forming a common electrode. Subsequently, a positive phenol novolac photosensitive resin is applied by spin coating onto the substrate on which the common electrode is formed. Then, the applied photosensitive resin is exposed to light with a photomask, and then is developed, thereby forming a photo spacer.

In the manner described above, a counter substrate 30 can be fabricated.

<Bonding Step>

First, the surface of the active matrix substrate 10 is coated with a polyimide-based resin by printing, and then is subjected to rubbing, thereby forming an alignment film 33. The surface of the counter substrate 30 is also coated with a polyimide-based resin by printing, and then is subjected to rubbing, thereby forming an alignment film 34.

Next, a sealing material 32 of, for example, an ultraviolet-curing thermosetting resin is drawn in the shape of a rectangular frame with, for example, a dispenser on the counter substrate 30 on which the alignment film 34 is provided. Subsequently, a predetermined amount of a liquid crystal material is dropped onto a region inside the sealing material 32 on the counter substrate 30 on which the sealing material 32 is drawn.

Then, the counter substrate 30 onto which the liquid crystal material has been dropped and the active matrix substrate 10 provided with the alignment film 33 are bonded together under a reduced pressure, and the bonded assembly is released to the atmospheric pressure, thereby pressurizing the surface of the bonded assembly. Further, the sealing material 32 of the bonded assembly is irradiated with ultraviolet (UV) light so that the sealing material 32 is precured, and then the resultant bonded assembly is heated so that the sealing material 32 is postcured, thereby bonding the active matrix substrate 10 and the counter substrate 30 together. Thereafter, polarizing plates 35 and 36 are respectively attached to the surfaces of the active matrix substrate 10 and the counter substrate 30 which are bonded together.

<Packaging Step>

An ACF is provided on a region where each of driver IC chips 37 and 38 is mounted in the mounting portion 10a of the bonded assembly formed through the bonding step. Then, the driver IC chips 37 and 38 are thermocompression bonded to the mounting portion 10a with the ACFs interposed therebetween, thereby mounting the driver IC chips 37 and 38 on the bonded assembly.

Through the foregoing steps, the liquid crystal display device S illustrated in FIG. 1 is fabricated.

### Advantages of First Embodiment

As described above, in the active matrix substrate 10, the liquid crystal display device S including the active matrix substrate 10, and a method for fabricating the active matrix substrate 10 and the liquid crystal display device S according to the first embodiment, the gate electrode 14ad is provided on the layered structure 16 formed by successively stacking the metal layer 12a and the insulating layer 13a, and the dielectric layer 13b of the storage capacitor 17 is formed in the same layer and made of the same material as the insulating layer 13a of the layered structure 16, and is provided as a component different from the gate insulating film 18, thus allowing the dielectric layer 13b to have an intended thickness. Accordingly, the dielectric layer 13b of the storage capacitor 17 can be made thinner than the gate insulating film 18, and thereby, the capacitance of the storage capacitor 17 per a unit area can be increased. This structure enables the storage capacitor 17 to have a predetermined capacitance even with decreases in the areas of the upper electrode 14b and the lower electrode 12bd. That is, it is possible to reduce the area of the storage capacitor 17, while maintaining a predetermined capacitance thereof. In addition, as described in the active matrix substrate formation step as an example, it is possible to form the storage capacitor 17 including the dielectric layer 13b as a component different from the gate insulating film 18 without an additional photomask. Accordingly, an increase in the number of fabrication process steps and a decrease in the aperture ratio of pixels can be reduced, and the storage capacitor 17 having a desired capacitance can be obtained. As a result, display quality can be improved with simplified fabrication processes and a reduced fabrication cost.

### Second Embodiment

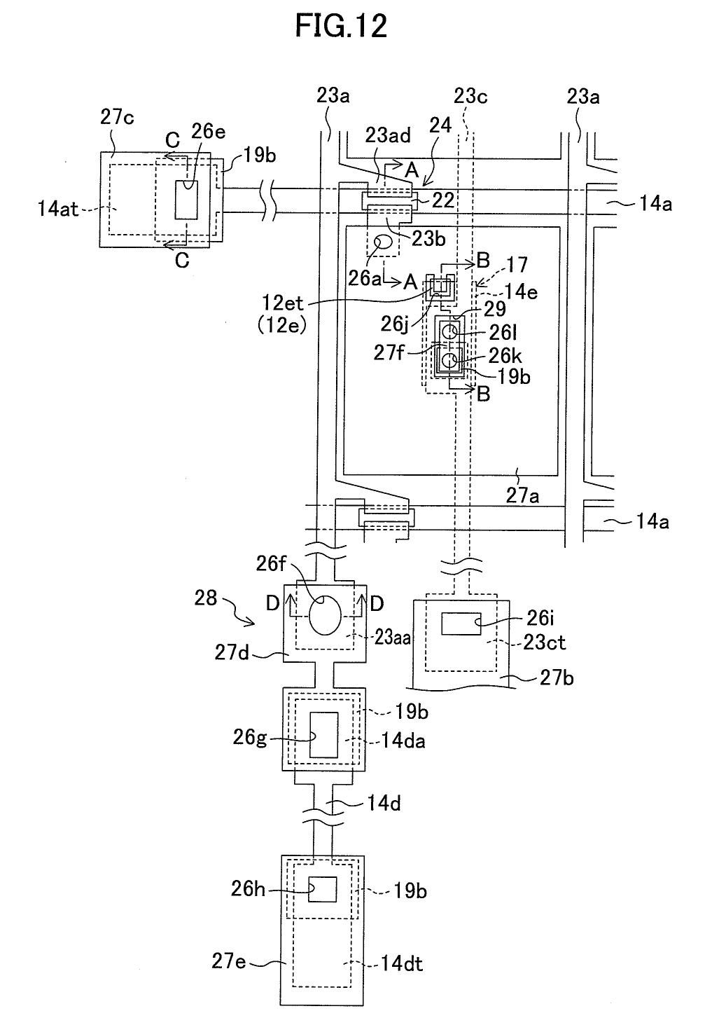

FIGS. 12 to 16 illustrate an active matrix substrate and a method for fabricating the active matrix substrate according to a second embodiment of the present invention. In the following embodiment, components already shown in FIGS. 1 to 11 are designated by the same reference characters, and explanation thereof is not repeated.

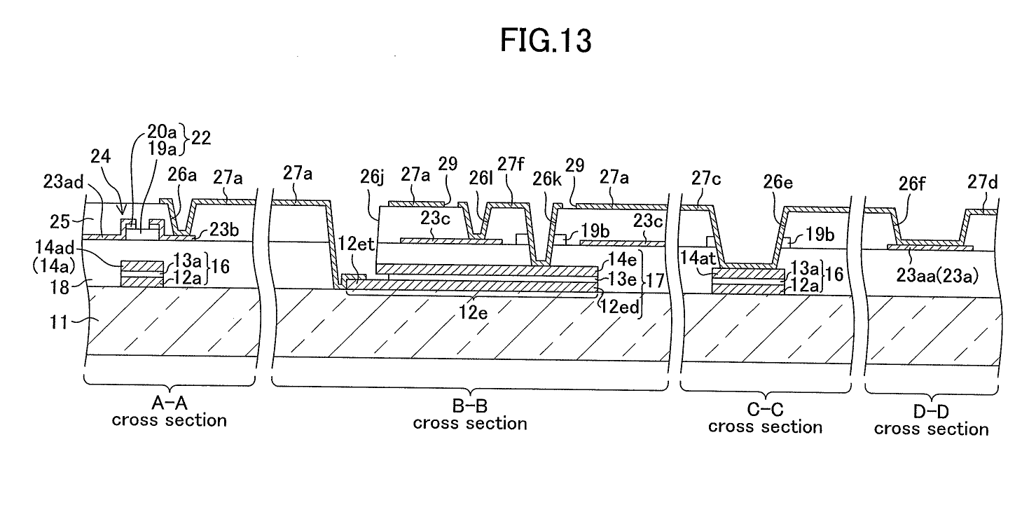

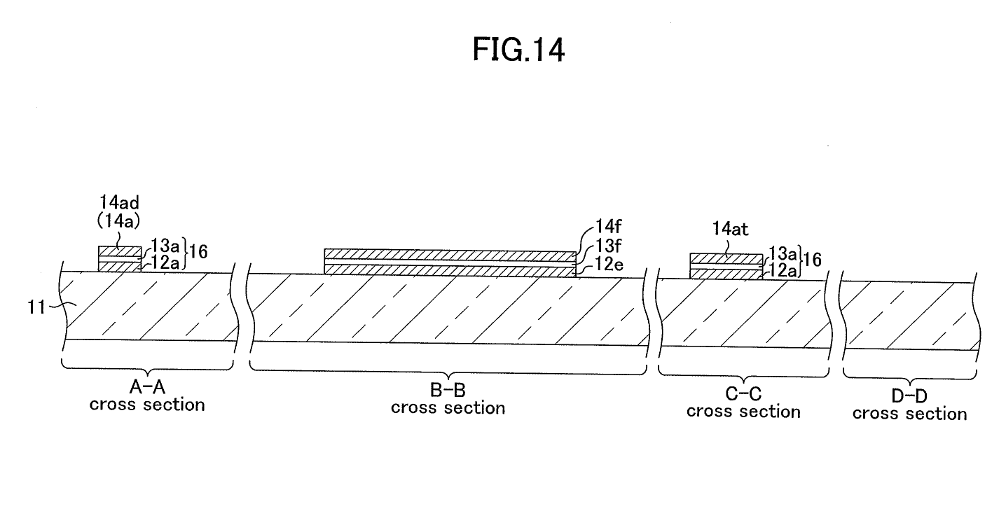

FIG. 12 is a plan view schematically illustrating a configuration of a pixel and terminals in an active matrix substrate 10 of this embodiment. FIG. 13 is a cross-sectional view schematically illustrating a configuration of a pixel and terminals in the active matrix substrate 10 of this embodiment. As described below, FIGS. 14 to 16 are views for describing a method for fabricating an active matrix substrate 10 according to this embodiment. FIG. 13 illustrates cross-sections taken along lines A-A, B-B, C-C, and D-D in FIG. 12 in this order from the left to the right in the drawing sheet.

In the first embodiment, in each of the storage capacitors 17, the upper electrode 14b is connected to the pixel electrode 27a via the contact hole 26b. On the other hand, in the second embodiment, in each of the storage capacitors 17, a lower electrode 12ed is electrically connected to a pixel,electrode 27a via a contact hole 26j.

The active matrix substrate 10 of this embodiment constitutes a liquid crystal display device S as in the first embodiment, and gate lines 14a and source lines 23a are arranged to form a lattice pattern in an overall layout and define pixels as illustrated in FIG. 12. As illustrated in FIG. 13 (specifically in an A-A cross section), each TFT 24 is a bottom-gate TFT as in the first embodiment, and a gate electrode 14ad is provided on a layered structure 16 formed by successively stacking a metal layer 12a and an insulating layer 13a.

As illustrated in FIG. 13 (specifically in a B-B cross section), each storage capacitor line 23c is provided on a gate insulating film 18, is formed in the same layer and made of the same material as a source electrode 23ad and a drain electrode 23b, and extends across a plurality of pixels arranged in the direction in which the source line 23a extends, as illustrated in FIG. 12. The storage capacitor line 23c extends to a region where a sealing material 32 is provided. Each end of the storage capacitor line 23c constitutes a common terminal 23ct illustrated in FIG. 12. The common terminal 23ct is connected to a common connecting electrode 27b via a contact hole 26i formed in an interlayer insulating film 25. The common connecting electrode 27b is electrically connected to a common electrode of a counter substrate 30, as in the first embodiment.

As illustrated in FIG. 13 (specifically in a B-B cross section), the storage capacitor 17 is covered with a gate insulating film 18 as in the first embodiment, and includes: a lower electrode 12ed associated with a pixel, a dielectric layer 13e provided on the lower electrode 12ed; and an upper electrode 14e overlapping the lower electrode 12ed with the dielectric layer 13e sandwiched therebetween. As in the first embodiment, the lower electrode 12ed is formed in the same layer and made of the same material as the metal layer 12a of the layered structure 16, the dielectric layer 13e is formed in the same layer and made of the same material as the insulating layer 13a, and the upper electrode 14e is formed in the same layer and made of the same material as the gate electrode 14ad.

A lower metal layer 12e constituting the lower electrode 12ed is partially exposed from the dielectric layer 13e and the upper electrode 14e, and the exposed portion constitutes a terminal 12et. The terminal 12et is connected to the pixel electrodes 27a via a contact hole (a second contact hole) 26j continuously formed in the interlayer insulating film 25 and the gate insulating film 18. On the other hand, the upper electrode 14e is connected to a connecting electrode 27f on the interlayer insulating film 25 via a contact hole (a first contact hole) 26k continuously formed in the interlayer insulating film 25 and the gate insulating film 18. The connecting electrode 27f is provided inside an opening 29 formed in the pixel electrode 27a, as a component different from the pixel electrodes 27a, and is connected to the storage capacitor line 23c via a contact hole 26l formed in the interlayer insulating film 25. In this manner, the upper electrode 14e is electrically connected to the storage capacitor line 23c.

—Fabrication Method—

Referring now to FIGS. 14 to 16, a method for fabricating the active matrix substrate 10 will be described.

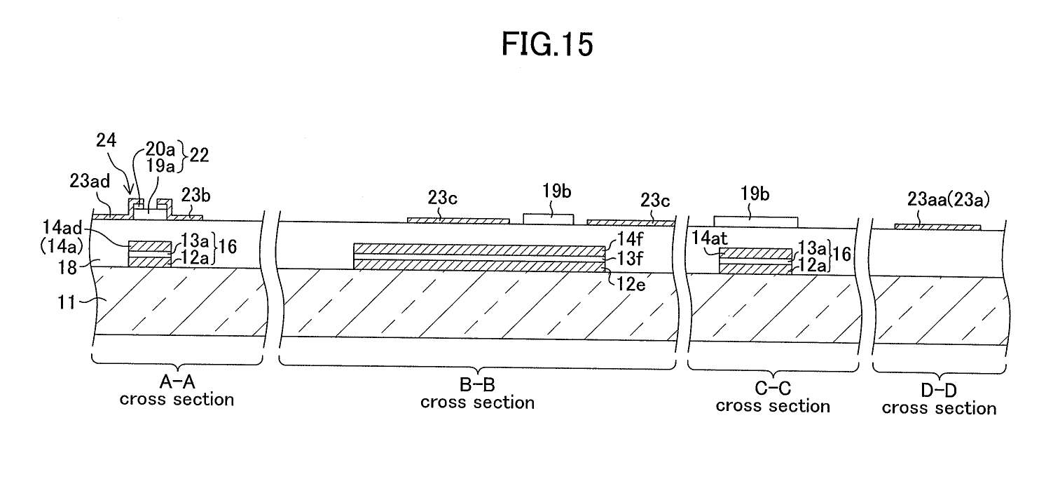

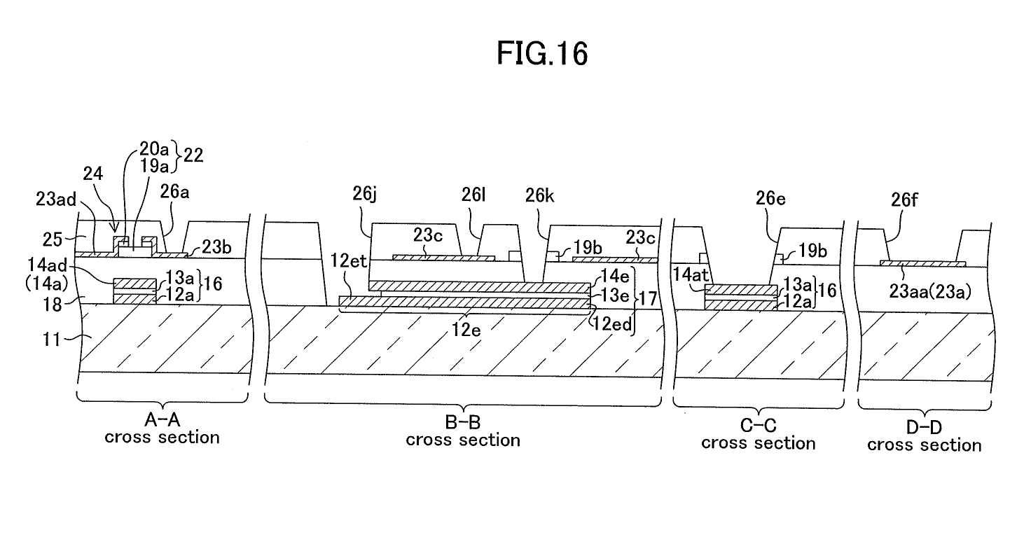

FIG. 14 is a cross-sectional view illustrating a state in which a multilayer film 15 is patterned such that a lower metal layer 12e, an insulating layer 13f, and an upper metal layer 14f for forming a storage capacitor 17, and a gate electrode 14ad are formed. FIG. 15 is a cross-sectional view illustrating a state in which a semiconductor layer 22, a source electrode 23ad, a drain electrode 23b, and a storage capacitor line 23c are formed. FIG. 16 is a cross-sectional view illustrating a state in which an interlayer insulating film 25 and a gate insulating film 18 are patterned such that contact holes 26a, 26e, 26f, 26j, 26k, and 26l are formed. FIGS. 14 to 16 respectively illustrate portions associated with cross sections (i.e., an A-A cross section, a B-B cross section, a C-C cross section, and a D-D cross section) in FIG. 13. FIGS. 14, 15, and 16 do not show resist layers.

A method for fabricating an active matrix substrate 10 according to this embodiment also includes a multilayer film formation step, a multilayer film patterning step, a gate insulating film formation step, a drain electrode formation step, an interlayer insulating film formation step, a contact hole formation step, and a pixel electrode formation step.

<Multilayer Film Formation Step>

As in the first embodiment, a metal film 12 such as an aluminium film, an insulating film 13 such as a silicon nitride film, and a metal film 14 such as a titanium film are successively formed by sputtering or plasma CVD over an insulating substrate 11 such as a glass substrate, thereby forming a multilayer film 15.

<Multilayer Film Patterning Step>

The metal film 12, the insulating film 13, and the metal film 14 in the multilayer film 15 formed on the insulating substrate 11 through the multilayer film formation step are patterned at a time by a photolithography process in which etching is performed using, as a mask, a resist layer formed with a first photomask. In this manner, as illustrated in FIG. 14, a metal layer 12a is formed out of the metal film 12, an insulating layer 13a is formed out of the insulating film 13, a gate line 14a and a gate electrode 14ad are formed out of the metal film 14 such that the metal layer 12a, the insulating layer 13a, and the gate line 14a including the gate electrode 14ad overlap. At the same time, a lower metal layer 12e is formed out of the metal film 12, an insulating layer 13f is formed out of the insulating film 13, an upper metal layer (an upper conductive layer) 14f is formed out of the metal film 14_such that the lower metal layer 12e, the insulating layer 13f, and the upper metal layer 14f overlap. Accordingly, the gate line 14a and the gate electrode 14ad are formed on a layered structure 16 concurrently with formation of the lower metal layer 12e, the insulating layer 13f, and the upper metal layer 14f for forming the storage capacitor 17. Thereafter, the resist layer used as a mask is removed by ashing. In this step, the insulating layer 13f and the upper metal layer 14f are stacked on the entire lower metal layer 12e.

<Gate Insulating Film Formation Step>

In the same manner as in the first embodiment, a silicon nitride film, for example, is formed by plasma CVD over a substrate on which the lower metal layer 12e, the insulating layer 13f, and the upper metal layer 14f for forming the storage capacitor 17, the gate line 14a, and the gate electrode 14ad are formed through the multilayer film patterning step, thereby forming a gate insulating film 18.

<Drain Electrode Formation Step>

In the same manner as in the first embodiment, a semiconductor multilayer film as a stack of an intrinsic amorphous silicon film and an n⁺ amorphous silicon film, for example, is formed by plasma CVD on the substrate on which the gate insulating film 18 is formed through the gate insulating film formation step. Then, the semiconductor multilayer film is patterned by a photolithography process in which etching is performed using, as a mask, a resist layer formed with a second photomask, thereby forming a semiconductor layer portion 22′ as a stack of an intrinsic amorphous silicon layer 19a and an n⁺ amorphous silicon layer 20a, and an etching stopper layer 19b on which an n⁺ amorphous silicon layer 20b is stacked. Thereafter, the resist layer used as a mask is removed by ashing.

Next, over the substrate on which the semiconductor layer portion 22′ and the etching stopper layer 19b are formed, a titanium film and an aluminium film, for example, are successively formed by sputtering, thereby forming a metal multilayer film. The metal multilayer film is patterned by a photolithography process in which etching is performed using, as a mask, a resist layer formed with a third photomask, thereby forming a source line 23a, a source electrode 23ad, a drain electrode 23b, and a storage capacitor line 23c. Thereafter, the resist layer used as a mask is removed by ashing.

Then, the n⁺ amorphous silicon layer 20a in the semiconductor layer portion 22′ is etched using the source electrode 23ad and the drain electrode 23b as a mask, thereby patterning a channel portion to form a semiconductor layer 22 and a TFT 24 including the semiconductor layer 22, as illustrated in FIG. 15. At this time, the n⁺ amorphous silicon layer 20b on the etching stopper layer 19b is also removed by etching.

<Interlayer Insulating Film Formation Step>

In the same manner as in the first embodiment, over the substrate on which the TFT 24 is formed through the drain electrode formation step, a silicon nitride film, for example, is formed by plasma CVD, thereby forming an interlayer insulating film 25.

<Contact Hole Formation Step>

The interlayer insulating film 25 formed through the interlayer insulating film formation step, the gate insulating film 18, the upper metal layer 14f, and the insulating layer 13f are patterned at a time by a photolithography process in which dryetching is performed with a fluorine-based gas such as CF₄ gas using, as a mask, a resist layer formed with a fourth photomask, thereby forming contact holes 26a, 26e, 26f, 26j, 26k, and 26l at a time as illustrated in FIG. 16, and also forming other contact holes 26g, 26h, and 26i at a time. In addition, at this time, the metal layer 14f and the insulating layer 13f in the contact hole 26j are removed so that the lower metal layer 12e is partially exposed, thereby forming a terminal 12et which is the exposed portion of the lower metal layer 12e, an upper electrode 14e out of the metal layer 14f, and an dielectric layer 13e overlapping the upper electrode 14e out of the insulating layer 13f. Accordingly, in the same manner as in the first embodiment, a storage capacitor 17 including the upper electrode 14e, the dielectric layer 13e, and a lower electrode 12ed made of a portion of the lower metal layer 12e where the upper electrode 14e and the dielectric layer 13e overlap each other, is formed together with the contact holes 26a, 26e, 26f, 26g, 26h, 26i, 26j, 26k, and 26l. At this time, since the drain electrode 23b and a lead end 23aa of the source line 23a serve as an etching stopper, etching on the regions where the contact holes 26a and 26f are to be formed is stopped when the drain electrode 23b and the lead end 23aa of the source line 23a are exposed. Etching on the regions where the contact holes 26e, 26g, 26h, and 26k are to be formed is inhibited by the etching stopper layer 19b, resulting in that etching on the regions where the contact holes 26e, 26g, 26h, and 26k are to be formed is performed more slowly than etching on the region where the contact hole 26j is to be formed. Accordingly, damage on the storage capacitor 17 caused by etching of the upper electrode 14e and the dielectric layer 13e, damage on an interconnection portion 28 caused by etching of an end 14da of a lead line 14d, damage on terminals 14at and 14dt caused by etching are reduced. Thereafter, the resist layer used as a mask is removed by ashing.

<Pixel Electrode Formation Step>

An ITO film, for example, is formed by sputtering over the substrate on which the contact holes 26a, 26e, 26f, 26g, 26h, 26i, 26j, 26k, and 26l are formed through the contact hole formation step. Then, the ITO film is patterned by a photolithography process in which etching is performed using, as a mask, a resist layer formed with a fifth photomask, thereby forming a pixel electrode 27a, a common connecting electrode 27b, a gate connecting electrode 27c, an interconnection electrode 27d, a source connecting electrode 27e, and a connecting electrode 27f. Thereafter, the resist layer used as a mask is removed by ashing.

In the manner described above, an active matrix substrate 10 can be fabricated.

### Advantages of Second Embodiment

As described above, in the second embodiment, the gate electrode 14ad is also provided on the layered structure 16 formed by successively stacking the metal layer 12a and the insulating layer 13a, and the dielectric layer 13e of the storage capacitor 17 is formed in the same layer and made of the same material as the insulating layer 13a of the layered structure 16, and is provided as a component different from the gate insulating film 18. Accordingly, the dielectric layer 13e of the storage capacitor 17 can be made thinner than the gate insulating film 18, and thereby, the capacitance of the storage capacitor 17 per a unit area can be increased. This structure enables the storage capacitor 17 to have a predetermined capacitance even with decreases in the areas of the upper electrode 14e and the lower electrode 12ed. That is, it is possible to reduce the area of the storage capacitor 17, while maintaining a predetermined capacitance thereof. In addition, as described for the active matrix substrate formation method, it is possible to form the storage capacitor 17 including the dielectric layer 13b as a component different from the gate insulating film 18 without an additional photomask. Accordingly, the same advantages as in the first embodiment can be obtained.

In the foregoing embodiments, each of the dielectric layers 13b and 13e of the storage capacitors 17 is formed out of the film (i.e., the silicon nitride film) made of the same material as the gate insulating film 18. However, the present disclosure is not limited to these embodiments, and each of the dielectric layers 13b and 13e of the storage capacitors 17 may be made of a material having a dielectric constant higher than that of a material used for the gate insulating film 18. This structure can also increase the capacitance of the storage capacitor 17 per a unit area, thus allowing the storage capacitor 17 to have a predetermined capacitance even with decreases in the areas of the upper electrodes 14b and 14e and the lower electrodes 12bd and 12ed. As a result, it is possible to reduce the area of the storage capacitor 17, while maintaining a predetermined capacitance thereof.

In addition, in the foregoing embodiments, the resist layers used as masks for patterning the interlayer insulating film 25 and the gate insulating films 18, for example, are removed. Alternatively, the pixel electrode 27a and the gate connecting electrode 27c may be formed with the resist layers left.

Further, in the foregoing embodiments, the liquid crystal display devices S and the active matrix substrates 10 forming the devices S have been described. However, the present disclosure is not limited to these devices and substrates, and is applicable to other display devices such as an organic electro luminescence (EL) display device and methods for fabricating such devices.

### INDUSTRIAL APPLICABILITY

As described above, the present disclosure is useful for an active matrix substrate, a liquid crystal display device including the active matrix substrate, and a method for fabricating an active matrix substrate. In particular, the present disclosure is suitable for an active matrix substrate required of reducing an increase in the number of fabrication process steps and a decrease in the aperture ratio of pixels to form a storage capacitor having a desired capacitance, a liquid crystal display device including the active matrix substrate, and a method for fabricating the active matrix substrate.

### DESCRIPTION OF REFERENCE CHARACTERS

S liquid crystal display device

10 active matrix substrate

11 insulating substrate (substrate)

12 metal film (first conductive film)

12a metal layer (conductive layer)

12b storage capacitor line (lower conductive layer)

12bd, 12ed lower electrode

12e lower metal layer (lower conductive layer)

13 insulating film

13a, 13c, 13f insulating layer

13b, 13e dielectric layer

14 metal film (second conductive film)

14a gate line

14at gate terminal

14b, 14e upper electrode

14c, 14f metal layer (upper conductive layer)

15 multilayer film

16 layered structure

17 storage capacitor

18 gate insulating film

19b etching stopper layer

22 semiconductor layer

23ad gate electrode

23b drain electrode

24 TFT (thin film transistor)

25 interlayer insulating film

26a-26l contact hole

26b, 26k first contact hole

26d, 26j second contact hole

26e third contact hole

27a pixel electrode

27b common connecting electrode (connecting electrode)

27f connecting electrode

30 counter substrate

31 liquid crystal layer

1. An active matrix substrate, comprising:
a thin film transistor;
a storage capacitor;
an interlayer insulating film overlapping the thin film transistor and the storage capacitor; and
a pixel electrode provided on the interlayer insulating film, and electrically connected to the thin film transistor and the storage capacitor via contact holes formed in the interlayer insulating film, wherein
the thin film transistor includes a gate electrode, a gate insulating film covering the gate electrode, and a drain electrode provided on the gate insulating film and electrically connected to the pixel electrode,
the gate electrode is provided on a layered structure formed by successively stacking a conductive layer and an insulating layer,
the storage capacitor includes a lower electrode formed in a same layer and made of a same material as the conductive layer, a dielectric layer provided on the lower electrode, formed in a same layer and made of a same material as the insulating layer, and an upper electrode formed in a same layer and made of a same material as the gate electrode to overlap the lower electrode with the dielectric layer sandwiched therebetween,
the contact hole for electrical connection to the storage capacitor is continuously formed in the interlayer insulating film and the gate insulating film, and
the dielectric layer, the upper electrode, the interlayer insulating film, and the gate insulating film are formed such that a lower conductive layer forming the lower electrode is partially exposed from the dielectric layer, the upper electrode, the interlayer insulating film, and the gate insulating film.

2. The active matrix substrate of claim 1, wherein
the thin film transistor includes a semiconductor layer connected to the drain electrode and overlapping the gate electrode with the gate insulating film sandwiched therebetween,
an etching stopper layer is provided between the interlayer insulating film and the gate insulating film, is formed in a same layer and made of a same material as the semiconductor layer, and overlaps the upper electrode,
a connecting electrode is provided on the interlayer insulating film, and is formed as a component different from the pixel electrode,
a contact hole for electrically connecting the connecting electrode and the storage capacitor is provided in the interlayer insulating film and the gate insulating film, and is formed as a component different from the contact hole for electrically connecting the pixel electrode and the storage capacitor,
one of the contact hole for electrically connecting the pixel electrode and the storage capacitor or the contact hole for electrically connecting the connecting electrode and the storage capacitor serves as a first contact hole for connection to the upper electrode, and the other contact hole serves as a second contact hole for connection to the lower conductive layer, and
the first contact hole is also formed in the etching stopper layer.

3. The active matrix substrate of claim 2, further comprising:
a gate line connected to the gate electrode is,
an etching stopper layer provided between the interlayer insulating film and the gate insulating film, formed in a same layer and made of a same material as the semiconductor layer, and overlapping a terminal of the gate line,
a gate connecting electrode provided on the interlayer insulating film,
a third contact hole for connecting the gate connecting electrode and the terminal of the gate line is formed in the interlayer insulating film and the gate insulating film, and
the third contact hole is also formed in the etching stopper layer overlapping the terminal of the gate line.

4. The active matrix substrate of claim 1, 2 or 3, wherein the upper electrode of the storage capacitor is electrically connected to the pixel electrode via the contact hole.

5. The active matrix substrate of claim 1, 2 or 3, wherein the lower electrode of the storage capacitor is electrically connected to the pixel electrode via the contact hole.

6. A liquid crystal display device, comprising:
the active matrix substrate of claim 1, 2 or 3;
a counter substrate opposed to the active matrix substrate; and
a liquid crystal layer provided between the active matrix substrate and the counter substrate.

7. A method for fabricating an active matrix substrate including a thin film transistor, a storage capacitor, an interlayer insulating film overlapping the thin film transistor and the storage capacitor, and a pixel electrode provided on the interlayer insulating film, and electrically connected to the thin film transistor and the storage capacitor via contact holes formed in the interlayer insulating film, the thin film transistor including a gate electrode, a gate insulating film covering the gate electrode, and a drain electrode provided on the gate insulating film and electrically connected to the pixel electrode, the method comprising:
successively stacking a first conductive film, an insulating film, and a second conductive film on a substrate, thereby forming a multilayer film;
patterning the first conductive film, the insulating film, and the second conductive film at a time, thereby forming the gate electrode out of the second conductive film, a lower conductive layer out of the first conductive film, an insulating layer out of the insulating film, and an upper conductive layer out of the second conductive film such that the lower conductive layer, the insulating layer, and the upper conductive layer overlap;
forming the gate insulating film such that the gate insulating film covers the gate electrode and the upper conductive layer;
forming the drain electrode on the gate insulating film;
forming the interlayer insulating film such that the interlayer insulating film covers the drain electrode and overlaps the upper conductive layer with the gate insulating film sandwiched therebetween;
patterning the interlayer insulating film, the gate insulating film, the upper conductive layer, and the insulating layer at a time, thereby forming a contact hole for electrical connection to the drain electrode in the interlayer insulating film and a contact hole for electrical connection to the storage capacitor in the interlayer insulating film and the gate insulating film, forming an upper electrode out of the upper conductive layer and a dielectric layer overlapping the upper electrode out of the insulating layer with the lower conductive layer partially exposed, to form the storage capacitor including the upper electrode, the dielectric layer, and a lower electrode made of a portion of the lower conductive layer overlapping the upper electrode and the dielectric layer; and
forming the pixel electrode on the interlayer insulating film such that the pixel electrode is electrically connected to the drain electrode and the storage capacitor via the contact holes.

8. The method of claim 7, wherein in the contact hole forming step, a first contact hole for connection to the upper electrode and a second contact hole for connection to the lower conductive layer are formed in the interlayer insulating film and the gate insulating film, and
in the pixel electrode forming step, the pixel electrode is formed to be electrically connected to the storage capacitor via one of the first contact hole or the second contact hole, and a connecting electrode is formed to be electrically connected to the storage capacitor via the other contact hole.

9. A liquid crystal display device, comprising:
the active matrix substrate of claim 4;
a counter substrate opposed to the active matrix substrate; and
a liquid crystal layer provided between the active matrix substrate and the counter substrate.

10. A liquid crystal display device, comprising:
the active matrix substrate of claim 5;
a counter substrate opposed to the active matrix substrate; and
a liquid crystal layer provided between the active matrix substrate and the counter substrate.
